(19) United States
(12) Patent Application Publication
(10) Pub. No.: US 2024/0038532 A1
(43) Pub. Date: Feb. 1, 2024

(54) METHOD FOR PRODUCING A III-N MATERIAL-BASED LAYER

(71) Applicant: COMMISSARIAT A L'ENERGIE ATOMIQUE ET AUX ENERGIES ALTERNATIVES, Paris (FR)

(72) Inventors: Matthew CHARLES, Grenoble Cedex 09 (FR); Guy FEUILLET, Grenoble Cedex 09 (FR); Carole PERNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/258,380

(22) PCT Filed: Dec. 22, 2021
(86) PCT No.: PCT/EP2021/087380

§ 371 Date: Jun. 20, 2023

(30) Foreign Application Priority Data
Dec. 22, 2020 (FR) FR 2013977

(51) Int. Cl. H01L 21/02

(52) U.S. Cl. CPC H01L 21/0254; H01L 21/02592; H01L 21/02381; H01L 21/02458; H01L 21/02639; H01L 21/0265; H01L 21/0243; H01L 33/007

(57) ABSTRACT

A method for obtaining at least one nitride layer based upon a III-N material includes the successive steps of providing a stack having a support substrate and a plurality of pads, each pad including at least one basal section and one germination section carried by the basal section; modifying the basal section so as to form a modified basal section having a lower rigidity that the basal section before modification; and epitaxially growing a crystallite from the top of at least some of the pads of an assembly and continuing the epitaxial growth so as to form the nitride layer on pads on the assembly.

### TECHNICAL FIELD OF THE INVENTION

The invention relates to the production of a III-N material-based layer, for example a nitride (N) obtained from at least one from among gallium (Ga), indium (In) and aluminium (Al). The invention has application, for example, in the field of optoelectronic devices comprising a plurality of light-emitting diodes (LED) of micrometric size, generally called micro-LEDs or also the production of power components, such as transistors or power diodes.

### STATE OF THE ART

For numerous microelectronic or optoelectronic applications, it is sought to produce layers made of III-N material, typically nitrides of at least one from among gallium, indium and aluminium. Specific applications relate, for example, to the production of micro-LEDs (μLED). Other specific applications can relate to the production of power electronics devices, such as power diodes or transistors, by production of HEMTs (High Electron Mobility Transistors) or also vertical transistors or diodes.

For these applications, it is necessary to use a nitride layer, for example gallium nitride GaN, which has:
a high thickness (typically greater than 5, even 8 μm 10⁻⁶ metres), and
a low dislocation density (typically less than 1^{E}8 cm⁻²).

A major challenge therefore consists of minimising the density of defects in the nitride layer obtained by epitaxy. Indeed, the performances of the microelectronic or optoelectronic devices made from these nitride layers are very sensitive to the density of structure defects such as dislocations.

These dislocations start with the difference of mesh parameters between the epitaxial layer and the substrate, as well as the coalescence of small grains which are to formed at the start of growth; these grains are slightly disoriented against one another, and they are joined by forming, at the coalescence seal, dislocations which then pass through the whole epitaxial structure.

The most direct way to resolve these problems consists of using substrates of the same nature as the layers that are sought to be subjected to epitaxy (homo-substrates). Typically, so-called freestanding or bulk GaN plates are used. These plates are only available in a diameter less than or equal to 100 mm, which is an obstacle to their industrialisation and at reasonable production costs on the industrial scale.

Currently, the most widely used solution for manufacturing freestanding GaN plates is the epitaxy of layers by HVPE (Hydride Vapour Phase Epitaxy) on substrate like sapphire. The growth is done so as to decrease the density of dislocations on the surface, and to have a final layer which is a few hundred micrometres (μm) thick. With these known solutions, the sapphire substrate can therefore be removed, by leaving a GaN layer which could be used as a plate. This solution has the disadvantage of being particularly expensive and long. Furthermore, it is difficult to implement on plates of a large diameter.

The known solutions for GaN growth from a silicon substrate do not make it possible to obtain very thick layers and having an acceptable dislocation density, typically less than 1^{E}8/cm².

The solutions considered to date for industrial applications are therefore mainly based on the use of hetero-substrates combined with so-called “epitaxial lateral overgrowth”, or ELOG, methods. This method, based on the use of a mask to block the dislocations, makes it possible to reduce the density of the latter. However, these dislocations are distributed in a non-uniform manner, which can pose a problem during the manufacture of devices.

Another solution consists of regrowing the material by epitaxy on pre-existing pads of this material: this is the so-called pendeo-epitaxy method. However, conventional pendeo-epitaxy solutions do not make it possible to remove, even significantly reduce, the appearance of defects generated by the coalescence of adjacent germs.

Patent application WO2019122461, describes a solution which consists of growing a nitride layer on pads, also called pillars. These pads comprise a creeping section surmounted on a crystalline section. More specifically, these pads are formed by etching of an SOI (silicon-on-insulator)-type substrate. The thin silicon film (active layer) and the buried oxide (BOX) layer of the SOI substrate, form, after etching, to respectively the crystalline section and the creeping section of each pad. After formation of the pads in the SOI substrate, crystallites are then grown by epitaxy on the surface of the pads. The crystallites join together during coalescence, the creeping sections being deformed to enable a coalescence without formation of defects, then form a nitride layer which continues its growth by thickening.

This solution has the disadvantage of being relatively expensive.

There is therefore a need consisting of proposing a solution to reduce, even to remove, at least some of the disadvantages that the known solutions have.

Other aims, features and advantages of the present invention will appear upon examining the following description and the accompanying drawings. It is understood that other advantages can be incorporated.

### SUMMARY OF THE INVENTION

To achieve this aim, according to an embodiment of the present invention, a method for obtaining at least one nitride layer with the basis of a III-N material is provided.

The method comprises the following successive steps:
providing a stack comprising a plurality of pads extending from a support substrate of the stack, the pads being distributed on the support substrate so as to form at least one pad assembly, each pad comprising at least:
   a basal, crystalline section, extending preferably from an upper face of the support substrate,
   a germination, crystalline section, carried by the basal section,
selectively modifying the basal section vis-à-vis the germination section so as to form a modified basal section having a lower rigidity than the basal section before modification. Thus, the basal section and more generally, the pad are made more easily deformable, in particular under the effect of a mechanical stress generated during the crystallite coalescence phase.
after modification of the basal section, epitaxially grow a crystallite from the top of at least some of said pads of the assembly and continue the epitaxial growth of the crystallites until coalescence of the crystallites carried by the adjacent pads of the assembly, so as to form said nitride layer on the plot assembly.

Thus, the method proposed provides to initially have pads, then to modify the crystalline basal sections, for example Si-based, in order to make them more easily deformable during the epitaxial growth step.

Under the force of a mechanical stress generated during epitaxy, the portion of the pad which is formed by the modified basal section can thus be deformed. Thus, when two crystallites which are supported by one same plot assembly come into contact and coalesce, the mechanical stresses generated by this contact are transferred to the pads and therefore to the basal sections. The latter are deformed, absorbing, due to this, some even all of the mechanical stresses. The appearance and the propagation of dislocations at the coalescence seals between the crystallites which form, for example, a III-N material platelet, can thus be considerably reduced, even avoided.

In particular, if the crystallites are disoriented against one another in the plane, wherein the substrate mainly extends (“twist”) or outside of the plane (“tilt”), the disorientation between crystallites results in the creation of a coalescence grain seal. This grain seal is highly energetic since it results from the superposition of stress fields of the defects which compose it. If the crystallites push on the pads which can be deformed as the method described enables, the adjacent crystallites are thus oriented in the plane or outside of the plane to minimise the total energy of the system, without grain seals forming. On the contrary, if the crystallites push on pads which cannot be deformed, there is a formation of grain seals and therefore the appearance of dislocations.

The method proposed enables:
that before the basal section modification step, the pads are relatively hardly deformable, and
that after the modification step and before the epitaxial growth step, the pads are made more deformable.

This has numerous advantages.

Indeed, it can be provided to considerably relax the stresses on the dimensions of the section of the pads before epitaxial growth. This section is taken in a plane substantially parallel to an upper face from which the pads extend. More specifically, the methods proposed enables that the pads, before the modification step, have a large section, and in particular, a section which would not enable the crystalline basal sections to be sufficiently deformed during the epitaxial growth in order to avoid the formation of dislocations. This initial pad section, since it is relatively large, can be obtained with a very wide choice of conventional manufacturing methods, such as ultraviolet photolithography which is inexpensive.

The modification step carried out on the crystalline sections, for example by reducing their section and/or by modifying their material by oxidation by modification, makes it possible to increase the capacity of these pads to be deformed, this in order to reduce, even avoid, dislocations.

The method proposed therefore makes it possible, by relaxing the dimensional stresses on the definition of the pads, to reduce the duration and the manufacturing cost of the III-N nitride layers and components made from these layers. Typically, with the solution described in document WO2019122461 mentioned above, the pads etched in the SOI substrate must have a very small section, for example less than 200 nm. This small dimension involves the use a highly expensive lithographic techniques which take a long time to implement. Typically, to form pads in the section is less than 200 nanometres, electron beam (E-beam) etching must be resorted to. This method is particularly long, since it requires to individually and successively define each of the pads. It becomes excessively expensive when it becomes necessary to produce numerous pads.

It will also be noted that the production of pads by nanoimprint, would also have disadvantages, in particular since these methods, particularly when they are used on an industrial scale, lead to a high effectiveness rate and a high dispersion in the definition of the patterns produced.

If the method proposed is particularly advantageous when the pads are defined by hardly limiting and inexpensive techniques such as ultraviolet photolithography, more complex techniques such as E-beam lithography or nanoimprint can fully be used to implement the method proposed.

Furthermore, the method proposed makes it possible to use crystalline basal sections having a relatively high thickness (the thickness is taken in a direction perpendicular to the upper face of the support substrate). It is thus possible to implement this method from bulk substrates. This type of substrates is a lot less expensive than developed substrates comprising a thin crystalline layer. It is, for example, the case of SOI substrates, wherein a thin crystalline layer (the active layer) is based on a dielectric layer which itself is based on a support substrate. SOI-type substrates are expensive and impact the price rise of manufacturing III-N material-based components.

Moreover, the method proposed makes it possible to obtain layers formed of III-N material, the coalescence of which is usually more complex to obtain. Such is the case for AlN. For these materials, the favoured growth direction is substantially perpendicular to the upper face of the base substrate. This direction, referenced as the to direction c, is not conducive to a rapid coalescence of the crystallites carried by the adjacent pads. Indeed, rapid coalescence requires having a significant growth in the plane perpendicular to the direction c (i.e. in a plane parallel to that of the upper face of the support substrate). The method proposed, by providing very narrow pads, makes it possible to closely bring the adjacent pads together. The distance between adjacent pads being reduced, the crystallites must grow over a very small distance to come into contact with the adjacent crystallites. The coalescence of the crystallites is thus achieved more rapidly. The method proposed thus makes it possible to reduce the time and the cost for obtaining III-N material layers, wherein the growth of the direction c is highly significant. The method proposed thus makes it possible to reduce the cost for obtaining AlN-based components, such as UV LEDs. More specifically, the coalescence from pads brought together makes a more rapid coalescence. Moreover, the growth from deformable pads makes it possible to reduce the density of dislocations in AlN. The crystalline quality of the AlN buffer layers is a significant factor for UV LEDs.

Moreover, the method proposed provides advantages of the method described in document WO2019122461, in terms of reduction, even removal, of dislocations at the coalescence seals between two crystallites. Thus, the method proposed makes it possible to obtain in a layer, even thick, of the densities of dislocation lower than those obtained with conventional on-silicon (Si) or on-silicon-carbide (SiC) or on-sapphire GaN growth solutions.

Thus, the method proposed makes it possible to obtain III-N material layers, having a significant thickness and a low density of dislocation. The method proposed is thus particularly advantageous for the production of microelectronic components, such as LEDs, power components, for example vertical transistors or HEMTs transistors.

### BRIEF DESCRIPTION OF THE FIGURES

The aims, objectives, as well as the features and advantages of the invention will best emerge from the detailed description of an embodiment of the latter, which is illustrated by the drawings.

FIGS. 1A to 1G illustrate steps of a non-limiting example of the method according to the present invention. FIG. 1A illustrates an example of a stack from which an example of the method according to the invention can be implemented. In this non-limiting example, several nitride layers, each forming a platelet, are formed on a base substrate.

FIG. 1B illustrates the stack of FIG. 1A, on which a germination layer is to formed.

FIG. 1C illustrates the result of a step consisting of forming pad assemblies from the stack of FIG. 1A or from that of FIG. 1B.

FIG. 1D illustrates a step of modifying crystalline sections. In this non-limiting example, this modification comprises a reduction of the section of crystalline sections.

FIG. 1E illustrates a phase or epitaxially growing crystallites, in particular on the top of the pads, this growth phase not being completed.

FIG. 1F illustrates the result of the epitaxial growth of crystallites, after coalescence of the crystallites carried by pads of one same assembly, the crystallites carried by pads of one same assembly thus forming a platelet.

FIG. 1G illustrates an optional step of producing a component, for example an LED with the formation of multiple quantum wells within each nitride platelet.

FIGS. 2 to 6 illustrate several embodiments to carry out the step of modifying basal sections so as to make them less rigid.

FIG. 2 illustrates an embodiment, wherein the modification step comprises a reduction by etching the section of crystalline basal sections.

FIG. 3 illustrates an embodiment, wherein the modification step comprises a transformation of the crystalline basal sections, for example by amorphisation of their material, so as to make them more easily deformable during epitaxial growth.

FIG. 4 illustrates an embodiment, wherein the modification step comprises a reduction by etching the section of the crystalline basal sections and an amorphisation of the crystalline basal sections.

FIG. 5 illustrates an embodiment, wherein the modification step comprises a porosification of the crystalline basal sections.

FIG. 6 illustrates an embodiment wherein the modification step comprises a porosification and an amorphisation of the crystalline basal sections.

FIGS. 7A to 7D illustrate, very schematically, a cross-sectional view of the different steps of an example of the method to form a III-N material year favouring the direction c during the epitaxial growth.

FIG. 8 is a top view corresponding to that of FIG. 7C.

The figures are given as examples and are not limiting of the invention. They are principle schematic representations intended to facilitate the understanding of the invention and are not therefore necessarily to the same scale as practical applications. In particular, the relative thicknesses of the different layers, sections, crystallites and platelets are not representative of reality.

### DETAILED DESCRIPTION OF THE INVENTION

Before starting a detailed review of embodiments of the invention, optional features are stated below, which can optionally be used in association or alternatively:

According to an example, providing the stack comprising a plurality of pads comprises:
providing a base structure comprising at least:
   a crystalline base substrate, preferably silicon-based, for example Si, SiGe or SiC,
   at least one germination layer surmounting the base substrate.
defining in the base structure, by etching through the whole thickness of the germination layer and only through a portion of the thickness of the base substrate, the plurality of pads.

Preferably, the etching defines, in the germination layer, the germination section of each pad. This etching also defines, in the base substrate:
the basal section of each pad, and
the support substrate from which the basal section of each pad extends.

According to an example, the section of the basal sections is greater than 100 nm (10⁻⁹ metres), preferably greater than 200 nm.

According to an example, the etching to define the plurality of pads in the structure, is done through an etching mask surmounting the germination layer, the etching mask preferably being made by ultraviolet photolithography.

According to an example, the modification is done such that the force F1 that must be applied to obtain a given deformation of the modified basal section is less than 0.8*F2 being the force that must be applied to obtain a deformation identical to the given deformation of the non-modified basal section, preferably, F1≤0.6*F2 and preferably, F1≤0.4*F2.

According to an example, selectively modifying the basal section comprises an etching of the basal section selectively to the germination section, so as to form a modified basal section having a section d₃₁₀ smaller than a section d₅₀₀ of the germination section, preferably d₃₁₀≤0.8*d₅₀₀ and preferably d₃₁₀≤0.5*d₅₀₀. According to an example d₃₁0≤0.8*d₃₀₀ and preferably d₃₁₀≤0.5*d₃₀₀. According to an example, the etching is an isotropic etching.

According to an example, selectively modifying the basal section comprises transforming the basal section so as to make the material of the basal section more easily deformable, in particular at a temperature T_{epitaxy} to which the stack is subjected to during the epitaxial growth. Thus, after transformation, the basal section has a lower rigidity than the basal section before modification.

According to an example, selectively modifying the basal section or transforming the material of the basal section comprises an at least partial amorphisation of the basal section, preferably selectively to the germination section, so as to form an amorphous modified basal section. According to an embodiment, the amorphisation is obtained by oxidation of the basal section, preferably selectively to the germination section. Thus, the basal section is modified by oxidation.

According to an example, the basal section is made of silicon and the modified basal section is made of SixOy, x and y being non-zero integers, preferably the SixOy being SiO2. According to an example, the oxidation is a thermal oxidation.

According to an example, the modified section thus behaves as a viscous material. Thus, the section modified by oxidation has a vitreous transition temperature T_{vitreous transition}.

According to an example, the epitaxial growth is achieved at a temperature T_{epitaxy}, such that:
T_{epitaxy}≥k1×T_{vitreous transition}, with k1≥0.8

According to an example, wherein k1≥1, and preferably k1≥1.5.

According to an example, the oxidation is done so as to oxidise the basal section on a thickness e₃₂₀ corresponding to less than half of the section d₃₀₀ of the basal section, the thicknesses e₃₂₀ and d₃₀₀ being taken in a plane parallel to a plane xy, wherein an upper face of the support substrate mainly extends. This, for example, makes it possible to make the basal sections more easily deformable during epitaxy. This also makes it possible to passivate the free faces of the basal sections so as to avoid an epitaxial growth on the basal sections.

According to an example, the oxidation is done so as to oxidise the whole section d₃₀₀ of the basal section, the section being taken in a plane parallel to a plane, wherein an upper face of the support substrate mainly extends. Thus, in this embodiment, e₃₂₀=d₃₀₀.

According to another embodiment, the transformation of the material of the basal section is obtained by nitridation of the basal section.

According to an example, selectively modifying the basal section comprises:
said transformation, preferably by oxidation, and
before or after the transformation, said etching of the basal section selectively to the germination section.

Preferably, the etching is done before amorphisation by oxidation, as it is desirable to have greater time and temperatures to achieve a thicker thermal oxidation.

According to an example, modifying the basal section comprises a porosification of the basal section, preferably selectively to the germination section.

Preferably, the Si substrate has or is a layer which is highly doped on the surface to limit the extension of the porosification.

According to an example, selectively modifying the basal section comprises:
said transformation and
after or, preferably before said transformation, said porosification of the basal section.

According to an example, selectively modifying the basal section comprises at least two and preferably the three following steps:
said transformation, for example by amorphisation of the basal section, and
said porosification of the basal section.
said etching of the basal section selectively to the germination section.

Preferably, the amorphisation is done after the porosification.

Preferably, the transformation, for example by amorphisation, is done after the porosification and the porosification is done after the etching.

According to an example, the pads are distributed over the support substrate so as to form a plurality of pad assemblies and the epitaxial growth step is interrupted before crystallites belonging to two distinct assemblies coalesce, such that the layer formed on each assembly forms a platelet, the platelets being distant from one another.

According to an example, the crystalline germination section, is made of a second III-N material, possibly identical to the III-N material of said nitride layer with the basis of a nitride III-N material. According to an example, the germination section is with the basis of one from among gallium (Ga), indium (In) and aluminium (Al).

According to an example, the crystalline germination section, is made of a material different from the material of the basal section.

According to an example, the basal section extends from an upper face of the support substrate.

According to an example, the basal section and the support substrate are formed of one same material.

According to an example, the basal section is made of or is with the basis of one from among silicon (Si), germanium (Ge), silicon germanium (Si—Ge), silicon carbide (SiC).

According to an example, the pads also comprise at least one buffer section, located between the basal section and the germination section.

According to an example, the basal section is Si-based, the buffer section is made of AlN and the germination section is made GaN. Preferably, the buffer section is directly in contact with the basal section. Preferably, the buffer section is directly in contact with the germination section.

According to an example, the basal section is Si-based, the germination section is made of AlN, the germination section preferably being directly in contact with the basal section.

According to an example, the germination sections are separated by a distance D and the section d₅₀₀ of the germination sections is such that D<d₅₀₀, preferably, D<0.7*d₅₀₀ and preferably D<0.5*d₅₀₀. This enables that the coalescence of the adjacent crystallites is rapidly done after the start of the epitaxial growth. This embodiment is particularly advantageous when the III-N material mainly grows in the direction c and a little rapidly in a plane xy perpendicular to the main direction z, wherein the pads extend. Preferably, the modified section d₃₁₀ of the basal sections 310 is such that d₃₁₀≤0.5*d₅₀₀.

According to an example, each of these layers has a lower face and an upper face, substantially parallel to an upper face of the substrate. Each layer forms a platelet. All the lower faces of the layers are substantially comprised in one same plane. The same goes for the upper faces.

According to an example, the modified basal section, for example by oxidation, is made of a viscous material. It has a viscoplastic transition.

According to an example, the epitaxial growth being carried out at a temperature T_{epitaxy}, such that: T_{epitaxy}≥k1×T_{vitreous transition}, with k1≥0.8.

Optionally, the epitaxial growth is carried out at a temperature T_{epitaxy}, such that:

T_{epitaxy}≥k1×T_{vitreous transition}, with k1≥0.8.

According to an example, k1=1, and preferably k1=1.5. According to an example of an embodiment, k1=0.87 or k1=0.9. According to a particularly advantageous example, k1=0.92. Thus, in the case where the modified basal sections are formed of SiO₂, T_{epitaxy}≥1104° C., T_{vitreous transition} for SiO₂ being equal to 1200° C. According to an even more preferable example of an embodiment, k1=0.95. According to an even more preferably example of an embodiment, k1=1, and preferably, k1=1.5.

In the embodiment wherein the pads are distributed over the support substrate so to as to form a plurality of pad assemblies and that the epitaxial growth step is interrupted before the crystallites belonging to two distinct assembles coalesce, such that the layer formed on each assembly forms a platelet, the platelets being distant from one another, the method can have at least any one of the following features and steps which can be combined or taken separately:

According to an example, the distance D separating two adjacent pads of one same assembly is less than the distance W1 separating two adjacent pads belonging to two different assemblies. W1>D and preferably W1≥2×D.

According to an example, W1≥k4×D, with k4=1.5, preferably k4=2. This makes it possible to have small pixels and a high integration density in the case of producing micro-LEDs. Preferably, k4=5. W1 can be equal to 1.5 microns.

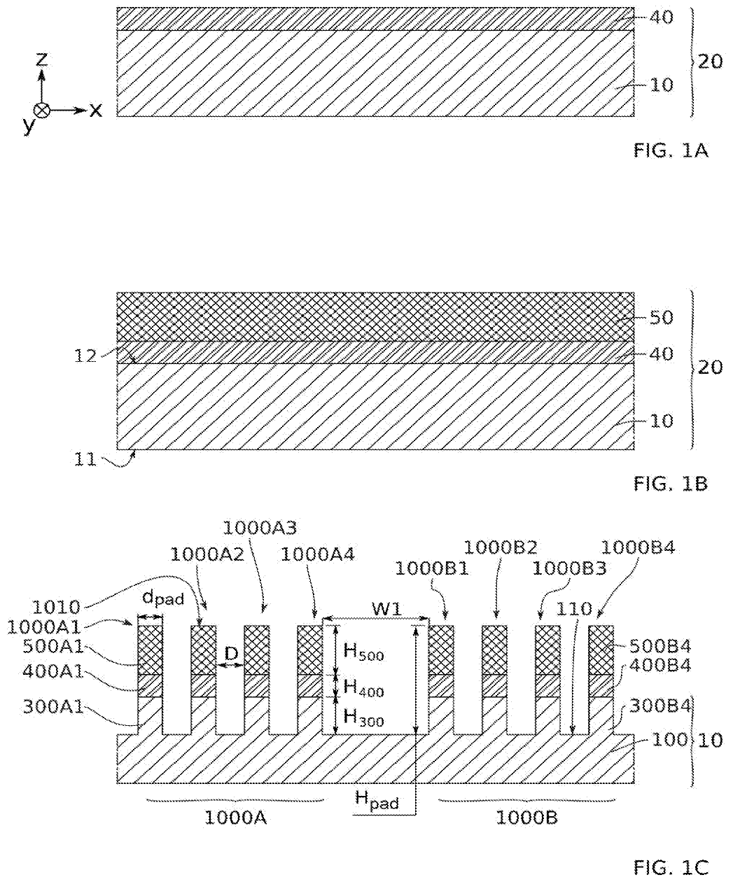

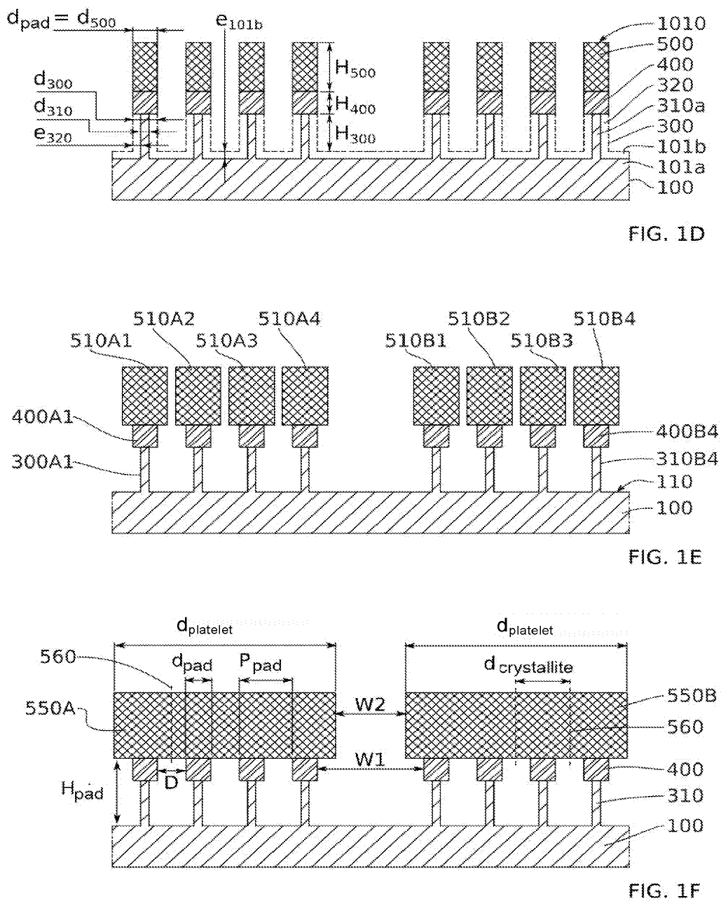

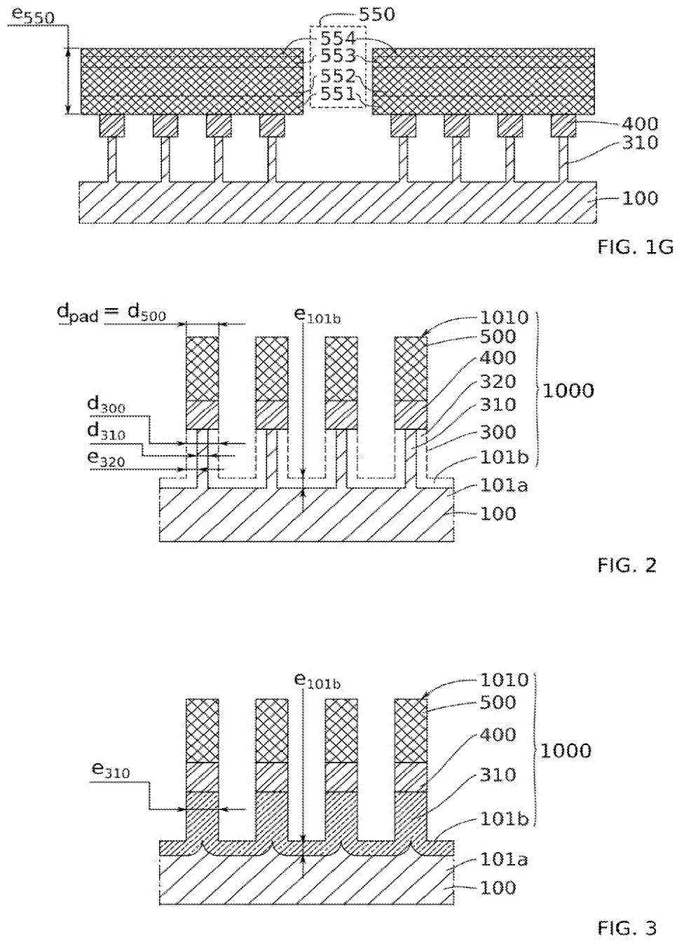

W2 being the distance separating two adjacent platelets (see W2 in FIG. 1F), it is necessary that W2 is non-zero such that the two adjacent platelets do not touch one another. Thus, W2>0.

According to an example, W1≥k5×W2, with:
W1 is the distance separating two adjacent pads belonging to two distinct assemblies;
W2 is the distance separating two adjacent platelets, W2 being>0. Preferably, k5=1.2, preferably k5=1.5, preferably k5=2.

According to an example, at least before the modification step, each pad has a section, the maximum dimension d_{pad} of which is between 10 and 500 nm (10⁻⁹ metres), the maximum dimension d_{pad} being measured in a plane parallel to a plane (xy), wherein an upper face of the substrate mainly extends, preferably d_{pad}<200 nm and preferably 50 nm d_{pad}<100 nm. d_{pad}=d_{padR} or d_{padS}.

According to an example, each platelet has a section, the maximum dimension dₚₗₐₜₑₗₑₜ of which is between 0.5 to 20 μm (10⁻⁶ metres), the maximum dimension dₚₗₐₜₑₗₑₜ being measured in a plane parallel to a plane (xy), wherein an upper face of the substrate mainly extends, preferably 0.8 μm≤dₚₗₐₜₑₗₑₜ≥3 μm and preferably 1 μm≤dₚₗₐₜₑₗₑₜ≤2 μm. The maximum dimension dₚₗₐₜₑₗₑₜ thus corresponds to the maximum dimension of a projection of the platelet in a plane parallel to the plane xy, wherein the upper face of the substrate mainly extends.

Alternatively, the pads of one same assembly are distributed over the substrate non-periodically. Optionally, but advantageously, the platelets are distributed over the substrate periodically.

According to an example, the pads comprises at least one buffer section surmounting the crystalline basal section. This buffer section is made of a material different from that of the nitride platelets. According to this example, the nitride platelets are made of gallium nitride (GaN) and the buffer layer is made of aluminium nitride (AlN). This makes it possible to avoid the appearance of the phenomenon of melt-back etching, generally by the very high reactivity between gallium and silicon. According to an example, each pad has an upper face also called top and the epitaxial growth of the crystallites is done partially at least and preferably only from said upper face.

According to an example, the basal section has a height h₃₁₀ such that h₃₁₀≥0.1λd_{pad}, dead being the diameter of the pad or more generally, the edge-to-edge distance of the pad taken, at the basal section and in a direction parallel to a plane (xy), wherein an upper face of the substrate mainly extends. Preferably, h₃₁₀≥1×d_{pad}. These values, make it possible to obtain a sufficient deformation to reduce the stresses at the grain seal.

According to an example, the pads have a height H_{pad}, and wherein two adjacent pads are distant by a distance D, such that: H_{pad}/D<2 and preferably H_{pad}/D≤1.

According to an example, the basal section, before modification, is silicon-based. Preferably, the basal section is made of silicon.

The crystalline basal section can also be with the basis of materials other than Si and which enable the epitaxy of nitride materials. For example, the crystalline basal section can be SiC- or Al₂O₃-based.

According to an example of an embodiment, the base substrate having served to form the crystalline basal section is a monocrystalline layer.

Preferably, crystals are epitaxially grown on all the pads.

According to an example of an embodiment, the nitride of the platelets is a nitride. According to another embodiment, the material forming the nitride (N) of the platelets is any one from among: gallium nitride (GaN), indium nitride (InN), aluminium nitride (AlN), aluminium gallium nitride (AlGaN), indium gallium nitride (InGaN), aluminium gallium indium nitride (AlGaInN), aluminium indium nitride (AlInN), aluminium indium gallium nitride (AlInGaN).

According to an example, the step of forming pads is carried out, such that d_{crystalize}/d_{pad}≥k3, with k3=3, d_{pad} being the maximum dimension of the section of the pad taken in a direction parallel to a plane (xy) wherein an upper face of the substrate mainly extends (pad, or more generally, the edge-to-edge distance of the pad, i.e. the maximum dimension of the pad, whatever the shape of its section), d_{crystallite} corresponding to the dimension of the crystallite measured in the same direction as d_{pad} at the time of coalescence of the crystallites.

Particularly effective results have been obtained for k3=3. According to an example, 100≥k3≥3. Preferably, 50≥k3≥3. Preferably, 5≥k3≥3.

The step according to which the pads of one same assembly are distributed is referenced P_{pad}. Preferably, P_{pad}/d_{pad}≥4, and preferably P_{pad}/d_{pad}≥5. According to an example which gives particularly qualitative results, P_{pad}/d_{pad}=5.

The term “micro-LED” means an LED, of which at least one dimension taken in a plane parallel to the main plane wherein the substrate supporting the micro-LED extends (i.e. the plane xy of the orthogonal system referenced in the figures) is micrometric, i.e. strictly less than 1 mm (10⁻³ metres). In the scope of the invention, the micro-LEDs have, projecting into a main extension plane parallel to the main faces of the micro-LEDs, i.e. parallel to an upper face of the substrate, maximum dimensions of micrometric dimension in the plane. Preferably, these maximum dimensions are less than a few hundred micrometres. Preferably, the maximum dimensions are less than 500 μm and preferably less than 100 μm.

In the present invention, by “HEMT-type transistors”) (High Electron Mobility Transistors), this means field-effect high electron mobility transistors, also referenced by the term of heterostructure field-effect transistor. Such a transistor includes the superposition of two semi-conductive layers having different band gaps which form a quantum well on their interface. Electrons are confined in this quantum well to form a two-dimensional electron gas. For reasons for maintaining high voltage and temperature, the materials of these transistors are chosen so as to have a wide energy band gap.

In the description below, the terms crystals and crystallites will be considered as equivalent.

It is specified that in the scope of the present invention, the terms “on”, “surmounts”, “covers” or “underlying” or their equivalents do not mean “in contact with”. Thus, for example, “the deposition of a first layer on a second layer” does not compulsorily mean that the two layers are directly in contact with one another, but this means that the first layer covers at least partially the second layer by being either directly in contact with it, or by being separated from it by at least one other layer or at least one other element including air. Likewise, “a pad surmounting a first layer” does not mean that the pad is necessarily in contact with this first layer, but means that the pad is, either in contact with this first layer, or in contact with one or more layers to disposed between the first layer and the pad.

The steps of forming different layers and regions mean in the broad sense: they can be carried out in several sub-steps, which are not necessarily strictly successive.

In the description below, the thickness or the height is taken in a direction perpendicular to the main faces of the different layers. In the figures, the thickness or the height is taken along the vertical or along the axis z of the orthogonal system illustrated in FIG. 1A.

Likewise, when it is indicated that an element is located to the right of another element, this means that these two elements are both located on one same line perpendicular to the main plane of the substrate, or on one same line oriented vertically (axis z) in the figures.

By a substrate, a layer, a device “with the basis” of a material M, this means a substrate, a layer, a device comprising this material M only, or this material M and optionally other materials, for example alloy elements, impurities or doping elements.

An example of a method for forming a nitride layer will now be described in reference to FIGS. 1A to 1G. In this non-limiting example, a plurality of layers made of III-N material is produced, each forming a platelet 550A, 550B (also called “vignette” or “disc”).

As illustrated in FIG. 1A, a base structure 20 is provided, comprising a base substrate 10, surmounted by at least one buffer layer 40.

The base substrate 10 is crystalline, preferably monocrystalline. According to an example, the base substrate 10 is silicon-based. Preferably, the base substrate 10 is a monocrystalline silicon bulk substrate. Alternatively, the base substrate 10 can be made of germanium (Ge), silicon germanium (SiGe) or also be SiC- or Al₂O₃-based.

According to a preferred example, the base substrate 10 is freestanding. It is not fixed to another substrate. Alternatively, the base substrate 10 itself rests on an additional substrate or an additional layer, fixed to its lower face 11.

The buffer layer 40 illustrated in FIG. 1A is preferably deposited by epitaxy on the upper face 12 of the base substrate 10. This buffer layer 40 is only optional.

When the platelets 550A, 550B that are sought to be ultimately obtained, are formed of GaN and that the base substrate 10 is a silicon-based layer, this buffer layer is typically made of aluminium nitride (AlN). This makes it possible to avoid the phenomenon called “melt-back etching”, generated by the very high reactivity between silicon and gallium at usual epitaxy temperatures (1000/1100° C.) and which leads to very high degrading the GaN platelets 550A, 550B.

Typically, the thickness of the AlN layer is between 10 and 100 nanometres (10⁻⁹ metres).

As illustrated in FIG. 1B, a germination layer 50 can also be epitaxially deposited, on the upper face of the buffer layer 40. This germination layer 50 has the function of facilitating the regrowth of crystallites 510 during following steps. In this case, it is from an upper face of the germination layer 50 that at least epitaxial growth of the crystallites 510A1-510B4 partially occurs, the crystallites being illustrated in FIG. 1E. This germination layer 50 is preferably made of the same material as that of the platelets 550A, 550B that are sought to be ultimately obtained. Typically, when the material of the platelets 550A, 550B is gallium nitride GaN, the germination layer 50 is also made of GaN. This germination layer 50 has, for example, a thickness of between and 200 nanometres.

Preferably, the buffer layer 40 is disposed directly in contact with the base substrate 10. Also, preferably, the buffer layer 40 is disposed directly in contact with the germination layer 50.

For concision and clarity, only four pads 1000A1-1000A4 are represented in the figures to support a platelet 550A. Naturally, a platelet 550A can be formed on a greater number of pads. As will be described below, the number of pads, as well as their period will be adapted according to the desired size for the microelectronic device, such as an LED, a transistor (of the HEMT type, for example) or a power diode, that is sought to be produced from this platelet.

As illustrated in FIG. 1C, pads 1000A1-1000B4 are then formed from the stack. These pads are obtained by etching of the stack until into the base substrate 10.

To form the pads by etching, numerous etching techniques known to a person skilled in the art can be resorted to. In particular, conventional lithographic techniques can be used, such as ultraviolet photolithographic techniques comprising the formation of a mask, for example made of resin, then the transfer of patterns from the mask into the stack. These etching techniques have the major interest of being rapid and inexpensive. Also, e-beam lithographic or nanoimprint techniques can be resorted to.

These pads 1000A1-1000B4 are small and can be qualified as nano-pads or nano-pillars. Typically, the maximum dimension of the section of the pads, taken in a plane parallel to the plane xy of the orthogonal system xyz or to the plane of the upper face 110 of the substrate 100, is between a few tens and a few hundred nanometres. This dimension is referenced d_{pad} according to the pads. Preferably, d_{pad} is between 50 and 1000 nanometres and preferably between 100 and 250 nm and preferably between to 200 and 500 nm, for example around 200 nm or 300 nm. This maximum dimension of the section of the pads is referenced d_{pad} in FIG. 1C. If the pads are of circular section, this maximum dimension d_{pad} corresponds to the diameter of the pads. If the pads are of hexagonal section, this maximum dimension d_{pad} corresponds to the diagonal or to the diameter of the circle passing through the angles of the hexagon. If these pads are of rectangular or square section, this maximum dimension d_{pad} corresponds to the largest diagonal or to the side of the square.

The pads 1000A1-1000B4 are not all regularly distributed on the surface of the substrate 100. In the example illustrated, the pads 1000A1-1000B4 form pad assemblies 1000A, 1000B, each assembly comprising a plurality of pads. The pads 1000A1-1000A4 forming one same assembly 1000A define a pad network distant from the pad network 1000B1-1000B4 forming another assembly 1000B.

Thus, the adjacent pads 1000A1-1000A4 of one same assembly 1000A are distant by a distance D. The adjacent pads 1000A4-1000B1 belonging to two distant assemblies 1000A, 1000B are separated by a distance W1. The distances D and W1 are taken in planes parallel to the plane xy and are illustrated in FIG. 1C. As will be explained below, the pads 1000A1-1000A4 of one same assembly 1000A are intended to support one single platelet 550A which will be distant from another platelet 550B supported by another pad 1000B1-1000B4 assembly 1000B.

It will be noted that for one same platelet, the distance D can vary. Thus, the pads 1000A1-1000A4 of one same platelet 550A can be non-periodically distributed. Their distribution can thus be adapted to favour the growth of the platelet. For example, if the arrangement of the pads 1000A1-1000A4 of a platelet 550A is not periodical, a distance D can be had, which varies for these pads 1000A1-1000A4 plus or minus 20% or plus or minus 10%, for example plus or minus 10 nm around an average value. According to an example, D can take the following values for one same platelet: 100 nm, 90 nm, 85 nm, 107 nm.

The platelets 550A, 550B formed on pad assemblies 1000A, 1000B non-periodically distributed can themselves be disposed periodically on the substrate. This facilitates the production of a microscreen.

The pads 1000A1-1000B4 are formed of a stack of sections. The sections extend in the main extension direction of the pad, i.e. vertically (z) in FIGS. 1A to 1G. Each section corresponds to one of the layers of the base structure 20. Thus, a first section referenced basal section 300 extends from a non-etched portion of the base substrate 10. This non-etched portion of the base substrate 10 defines a support substrate 100 to for the pads 1000A, 1000B. The basal section 300 and the support substrate 100 are formed in the base substrate 10. Thus, the basal section 300 has a continuity of material with the support substrate 100. The pads 1000A1-1000B4 comprise, above the basal section 300, a germination substrate 500 and optionally buffer substrate 400. The germination substrate 500 and the buffer substrate 400 correspond respectively to the non-etched portion of the germination layer 50 and to the non-etched portion of the buffer layer 40.

The sections of one same pad substantially have the same section. Preferably, the sections are solid. The section of the sections is taken parallel to the plane xy, is parallel to the planes, wherein the faces of the base substrate 10 mainly extend. According to an example of an embodiment, the basal sections 300 of the pads 1000A1-1000B4, have a height H₃₀₀, referenced in FIG. 1C. As a reminder, d_{pad} is the maximum dimension of the section of the pad taken in a direction parallel to a plane (xy), wherein an upper face of the substrate mainly extends. Preferably, H₃₀₀ is such that, if the etching technology imposes d_{pad}>50 nm, it is preferable that H₃₀₀>2*d_{pad} is H₃₀₀>100 nm, preferably H₃₀₀>150 nm. For d_{pad}=150 nm, it must preferably be that H₃₀₀>300 nm, etc. It will be noted that advantageously this height is greater than the usual thickness of the active crystalline layer of an SOI-type substrate.

According to an example of an embodiment, the buffer sections 400, have a height H₄₀₀. Preferably, H₄₀₀ is greater than 50 nm. Preferably, H₄₀₀ is greater than 100 nm. Preferably, H₄₀₀ is greater than 150 nm. According to an example, H₄₀₀ is between 100 nm and 300 nm.

According to an example of an embodiment, the germination sections 500, have a height H₅₀₀. Preferably, H₅₀₀ is greater than 100 nm. Preferably, H₅₀₀ is greater than 200 nm. According to an example, H₅₀₀ is between 100 nm and 2 μm.

The heights H₃₀₀, H₄₀₀, H₅₀₀ of the sections 300, 400, 500 are measured in a direction z perpendicular to the main plane xy, wherein an upper face 110 of the base substrate 100 mainly extends, the basal sections 300 extending from this upper face 110.

Preferably, H₃₀₀/D<1, and preferably H₃₀₀/D<1.5. Preferably, H₃₀₀/D<2. As indicated above, D corresponds to the lowest distance separating two adjacent pads before epitaxial growth of the crystallites. D is measured parallel to the plane xy.

Each pad has a height, referenced H_{pad}, corresponding to the sum of the heights of its sections.

According to an example, such that:

H_{pad}/D<2, and preferably H_{pad}/D<1.5. Preferably, H_{pad}/D≤1. H_{pad} is measured in the direction z.

As illustrated in FIG. 1C, the pads are etched through the whole germination layer 50, the whole buffer layer 40 (when the latter is present). Preferably, only some of the thickness of the base substrate 10 is etched.

FIG. 1D illustrates the step of modifying the pads 1000A1-1000B4. This step is also illustrated in FIG. 2. This step is configured so as to make, at least the basal sections 300, more deformable. From this step, the basal sections 300 are modified, for example in terms of geometry or in terms of materials. Consequently, if the crystallites 510A1-510A1 carried by two adjacent pads 1000A1-1000A2 are disoriented against one another, during the coalescence of these two crystallites, the seal 560 formed at their interface, usually references grain seal or coalescence seal, will be formed without dislocation to make up for these disorientations. These coalescence seals are illustrated in FIG. 1F. The deformation of the modified basal seals 310 thus makes it possible to make up for these disorientations and to obtain platelets 550A, 550B without or with barely any dislocations at the coalescence seals 560. Thus, the step of modifying the basal section 300 is such that it enables, during the coalescence of the crystallites 510A1-510B4, the deformation of the basal section 300 such that the crystallites 510A1-510B4 can be oriented to make up for a disorientation of crystallites 510A1-510A1 carried by two adjacent pads 1000A1-1000A2. In other words, the step of modifying the basal section 300 is such that it enables, during the coalescence of the crystallites 510A1-510B4, the deformation of the basal section 300 such that the crystallites 510A1-510B4 can be oriented to minimise the energy of the system.

In the example illustrated in FIG. 1D, this modification step comprises a reduction of the section of the basal sections 300.

Before the modification step, the basal sections 300 have a section d₃₀₀. From the modification step, they each have a section d₃₁₀ such that d₃₁₀<0.8*d₃₀₀. Preferably, d₃₁₀<0.6*d₃₀₀, and even more preferably d₃₁₀<0.5*d₃₀₀. The references d₃₀₀ and d₃₁₀ are indicated in FIGS. 1D and 2. According to an example, d₃₁₀<100 nm. Preferably, d₃₁₀<50 nm.

Preferably, this etching makes it possible to etch the material of the basal sections 300 selectively to the other sections of the pads. Preferably, this etching is isotropic. Preferably, this etching is a wet etching. This can also be an isotropic dry etching. Thus, it consumes a part 101a of the support substrate 100 not being etched.

In a non-limiting example, wherein the basal section 300 is silicon-based, the buffer section 400 is made of AlN, and the germination section 500 is made of GaN, a wet etching based on an XeF2-based dry etching solution can be provided.

The thickness e₃₂₀ of the basal section 300 consumed during this etching is referenced in FIG. 2. This thickness e₃₂₀ is preferably time-controlled.

FIG. 1E illustrates the formation of crystallites 510A1-510B4 by epitaxial growth from the germination layer 50.

As illustrated in this FIG. 1E, the pads 1000A1-1000B4 each support a crystallite 510A1-510B4 carried by a stack of sections 500A1-400B4, 400A1-400B4, 300A1-300B4.

Whatever the embodiment retained, i.e. with or without buffer layer 40, the epitaxial growth of the crystallites 510A1-510B4, is partially done at least or only from the upper face 1010 of the pad 1000A1-1000B4, also referenced top 1010 of the pad. This makes it possible, in particular, to rapidly obtain crystallites 510A1-510B4 of high thickness.

It will be noted that the upper faces of the buffer layer 40 and of the germination layer 50, i.e. the faces rotated facing the platelets 550A, 550B that are sought to grow, have gallium (Ga)-, and not nitrogen (N)-type polarities, which considerably facilitates the obtaining of high quality epitaxial nitride platelets 550A, 550B.

The growth of the crystallites 510A1-510B4 is continued and extends laterally, in particular along planes parallel to the plane xy. The crystallites 510A1-510B4 of one same pad 1000A1-1000A4 assembly 1000A are developed until coalescing and forming a unit or platelets 550A, 550B as illustrated in FIG. 1F.

In other words, and as this clearly emerges from the figures, each platelet 550A, 550B extends between several pads 1000A1-1000A4. Each platelet 550A, 550B forms a continuous layer.

Thus, from step 1F, a plurality of platelets 550A, 550B is obtained, each platelet 550A being supported by the pads 1000A1-1000A4 of one same pad assembly 1000A. Two adjacent platelets 550A, 550B are separated by a distance W2, W2 being the lowest distance taken between these two platelets. W2 is measured in the plane xy.

W2 depends on W1, on the duration and on the speed of the epitaxial growth. W2 is non-zero. W2<W1.

The maximum dimension dₚₗₐₜₑₗₑₜ of a platelet measured parallel to the plane xy. Thus, dₚₗₐₜₑₗₑₜ corresponds to the maximum dimension of a projection of the platelet in a plane parallel to the plane xy. According to an example, 0.8 μm≤dₚₗₐₜₑₗₑₜ≤3 μm. to According to another example, 1 μm≤dₚₗₐₜₑₗₑₜ≤2 μm. According to an example, dₚₗₐₜₑₗₑₜ is between 10 μm and 200 μm. Such is the case, for example, for vertical MOSFET transistors. According to an example, dₚₗₐₜₑₗₑₜ is around 1000 μm. Such is the case, for example, for HEMT-type power transistors. Dₚₗₐₜₑₗₑₜ depends on the speed and on the duration of the epitaxial growth, as well as the number, of the dimension and of the step P_{pad} of the pads of one same assembly.

The method for producing platelets 550A, 550B can be stopped from FIG. 1F. Alternatively, this method can be followed to form a device integrating the III-N material layer. When the III-N material layer forms a platelet, the method can be followed to form, for example, a micro-LED, a diode or a transistor from each of the platelets 550A, 550B.

FIG. 1G illustrates a non-limiting embodiment, wherein quantum wells 590 are produced within each platelet 550. This embodiment advantageously makes it possible to directly produce a micro-LED of size corresponding to the initial size of the platelet. To produce quantum wells 590 within each platelet 500, a person skilled in the art can implement the known solutions of the state of the art. Thus, once the crystallites 510 have coalesced, the same growth conditions are adopted for the wells, as during a conventional two-dimensional growth.

The smallest dimension possible for micro-LEDs is in accordance with the ultimate resolution of the chosen structuring methods: for example, for networks developed by nanoimprinting, pad sizes of 50 nm and periods P_{pad} of 150 to 200 nm are reached. This is therefore around the pixel sizes sought for high-resolution μ-displays.

In the example described above, in reference to FIGS. 1A to 1G, the pads 1000 are distributed over the substrate 100, so as to form distinct assemblies 1000A, 1000B, such that a III-N material layer is formed on each assembly, and that the epitaxial growth is interrupted before the different layers come into contact, thus forming platelets 550A, 550B distinct and separated on the substrate 100.

Naturally, all the features, steps and technical advantages mentioned in reference to this embodiment are applicable to an alternative embodiment, wherein one single layer on the substrate 100 is produced. In this case, it can be provided that there is no discontinuity between pad assemblies. In any case, it is provided to continue the epitaxial growth until a continuous layer is formed on the pads. In this case, it will naturally be ensured to distribute the pads such that the epitaxial growth from pads forms this continuous layer. For example, W1=D and W2=0. Preferably, this layer covers at least 50%, preferably at least 80% of the upper face of the substrate 100.

In each of these two embodiments, i.e. with formation of one single layer on the substrate or formation of a plurality of layers each forming a platelet, the coalescence is done without, or with few dislocations within the III-N material layer. Moreover, this low density of dislocations can be obtained, even though the thickness of the III-N material layer is high, typically greater than 5 μm, even greater than 8, even 20 μm. As indicated above, the step of modifying basal sections makes the latter less rigid. This lower rigidity can, for example, be verified by applying a force, for example, a twisting about an axis parallel to the plane of the upper face of the support substrate:
on the top of a pad before modification, then
on the top of a pad after modification.

This force can also be applied on the basal section itself. The deformation difference of the pad or of the basal section can thus be measured, when an identical force is applied before and after modification.

According to an example, the reduction in rigidity of the basal section or of the pad is greater than 20% and preferably greater than 50%. According to an example, the force F1 that must be applied to obtain a given deformation of the modified basal section 310 is less than 0.8*F2, F2 being the force that must be applied to obtain an identical deformation of the non-modified basal section 300. Preferably, F1≤0.6*F2. Preferably, F1≤0.4*F2.

For a thinned pad without modification, the ratio between F2 and F1 can simply be the ratio of the sections of radii of the pads. If the material of the pad is transformed, for example by amorphisation, the elastic moduli of the material before and after modification must thus be involved. For example, if without modification of the pad, diameter ratios must be of a factor of two, such that the same force applied produces the same “deformation”, this factor can become equal to 1, if the elastic moduli, after deformation, are decreased by a factor of two.

Several embodiments can be considered to carry out the step of modifying basal sections 300. A few of these embodiments will now be described in detail, in reference to FIGS. 2 to 6.

Modification by Reduction of the Section of the Basal Sections

FIG. 2 schematically illustrates the embodiment of FIG. 1D. In this embodiment, the modification of the basal section 300 is obtained by reduction of its section using an etching, preferably isotropic. The details of this embodiment have been indicated above in reference to FIG. 1D.

This embodiment has the advantage of resting on well-known techniques. Moreover, it can be implemented at a low temperature. It does not involve limitation either, in terms of doping of the silicon.

The embodiments also make it possible to form basal sections 300 from particularly hard materials, such as Al₂O₃ or SiC.

According to an advantageous example, it is provided to form a passivation layer on the surface of the basal sections 300 before regrowth of the nitride with the basis of a III-N material (for example, GaN). This makes it possible to avoid that the epitaxial growth occurs at the basal sections 300. Such could be the case, if these basal sections 300 are made of silicon-based silicon. To form this passivation layer, an oxidation or a nitridation of only one portion of the thickness of the basal sections 300 can be provided. This passivation layer extends naturally from the external face of the basal sections 300. To this end, a very slight oxidation or a nitridation can be provided, for example with NH₃ before the epitaxial growth.

Moreover, this passivation layer avoids the appearance of the phenomenon of melt-back etching, which can occur when GaN and Si are in contact.

Modification by Transformation of the Material of the Basal Sections

FIG. 3 illustrates an embodiment, wherein the modification of the basal section 300 is obtained by transformation of the crystalline material constituting the basal section 300. This transformation means that the material of the basal section 300 becomes more easily deformable, in particular at the temperature T_{epitaxy} to which the stack is subjected during the epitaxial growth. After transformation, the basal section 300 thus has a lower rigidity than before transformation.

According to an example, this transformation is obtained by at least partial nitridation of the crystalline material. According to a preferred example, the transformation is obtained by amorphisation of the crystalline material. Preferably, the amorphisation is obtained by oxidation of the crystalline material. The modified basal section 310 thus has a material different from that of the basal section 300. Preferably, this modification is made in the whole section d₃₀₀ of the basal section 300.

Preferably, this oxidation does not alter the sections 400, 500 surmounting the basal section 300. This oxidation is therefore selective.

In this embodiment, the basal section 310 modified by oxidation is made of a viscous material. It thus has the behaviour of the vitreous transition or viscoplastic transition materials. In particular, it can be characterised by its vitreous transition temperature T_{vitreous transition}. Like all materials having a vitreous transition temperature, the creeping section 300, under the effect of a temperature increase, is deformed to without breaking and without returning to its initial position after a drop in temperature.

Particularly advantageously, the temperature T_{epitaxy} at which the epitaxy is done is greater than or around the vitreous transition temperature T_{vitreous transition} of the material constituting the modified basal section 310. Thus, during epitaxy, the modified basal section 310 is brought to a temperature which itself makes it possible to be deformed. It can creep. It can be qualified as a creeping section.

Consequently, if the crystallites 510A1-510A1 carried by two adjacent pads 1000A1-1000A2 are disoriented against one another, during the coalescence of these two crystallites, the deformation of the modified basal sections 310 thus makes it possible to make up for these disorientations and to obtain platelets 550A, 550B without or with very few dislocations at the coalescence seals 560.

In practice, T_{epitaxy}≥600° C. (in the scope of an epitaxy by molecular jets), T_{epitaxy}≥900° C. and preferably T_{epitaxy}≥1000° C. and preferably T_{epitaxy}≥1100° C. These values make it possible to particularly effectively reduce the defects in the platelet or the epitaxial layer, when the basal sections 300, initially made of Si, become made of SiO₂ after the step of modifying by oxidation. In practice, T_{epitaxy}<1500° C.

In order to facilitate the formation of coalescence seals 560 without dislocation, it will be preferable to apply the following conditions:

T_{epitaxy}≥k1×T_{vitreous transition}, with k1=0.8, preferably k1=1 and preferably k1=1.5.

According to an example of an embodiment, T_{epitaxy}≤k2×T_{min melting} T_{min melting} being the lowest melting temperature from among the melting temperatures of the sections forming the pad. According to an example of an embodiment, k2=0.9. This makes it possible to avoid a diffusion of the species of the material, the melting temperature of which is lower. If the buffer section 400 and the germination section 500 are made of AlN, and made of GaN, the melting temperatures of which are greater than 2000 degrees, the diffusion risk will be avoided.

Preferably, the modified basal section 310 is a silicon oxide SixOy, (x and y being non-zero integers), such as SiO₂.

As an example, for example a thermal oxidation can be carried out.

Preferably, this oxidation isotropically affects the material of the base substrate 10. Thus, a portion 101b of the support substrate 100 supporting the basal sections 300 are also oxidised. The portion of the support substrate 100 which is not oxidised is referenced 101a in FIG. 3.

In more detail, this oxidation could be done with the following parameters: 1000° C. under oxygen or 950° C. under vapour. The time varies with the pillar size.

A person skilled in the art will also know how to adapt the oxidation speed. For this, they can, for example, refer to the publication, Thermal Oxidation of Structured Silicon Dioxide, Thomas Lehrmann Christiansen, Ole Hansen, Jurgen Arendt Jensen, and Erik Vilain Thomsen, published on 5 Mar. 2014 in The Electrochemical Society ECS Journal of Solid State Science and Technology, Volume 3, Number 5.

This embodiment also has the advantage of avoiding, that during epitaxy, the nitride of the platelets 550A, 550B grows from crystalline portions of the basal sections 300 or of the upper face 110, crystalline, of the support substrate 100. Making the basal sections 300 and the upper face 110 of the support substrate 100 amorphous by oxidising them, prevents an undesired epitaxy on these surfaces.

This embodiment makes it possible to obtain particularly deformable modified basal sections 310, in particular at conventional epitaxial temperatures. Moreover, it is not required to implement complex of expensive steps of the method.

Moreover, this embodiment avoids the appearance of melt-back etching mentioned above

Modification by Etching and Transformation of the Basal Sections, for Example by Amorphisation

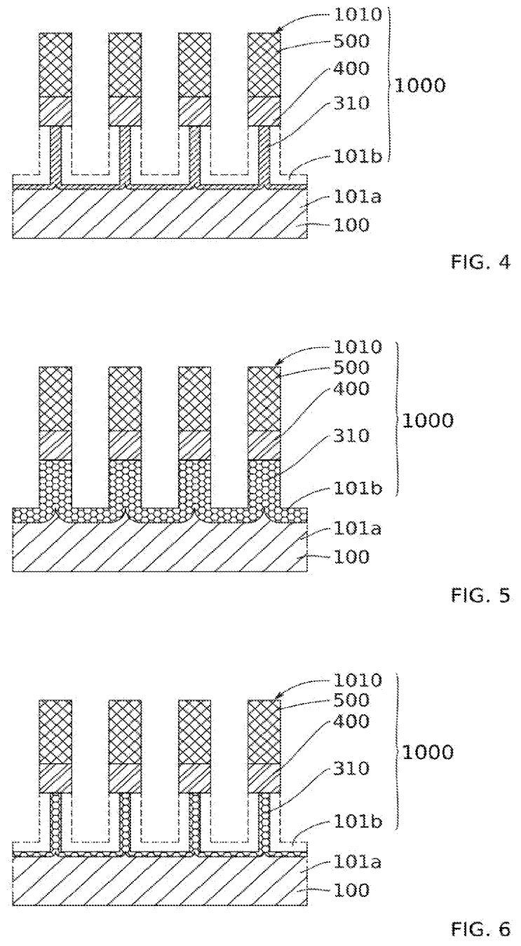

FIG. 4 illustrates an embodiment, wherein the modification of the basal section 300 is obtained by:
reducing the section of the basal section 300, and
amorphisation, preferably by oxidation, of the crystalline material constituting the basal section 300.

Thus, this embodiment corresponds to a combination of the embodiments described above, in reference to FIGS. 2 and 3. All the features, steps and technical effects mentioned above in reference to FIGS. 2 and 3 are applicable to the embodiments illustrated in FIG. 4.

Preferably, the reduction of the section of the basal section 300 by etching is done before amorphisation.

Alternatively, the reduction of the section of the basal section 300 by etching is done after amorphisation. This embodiment has the advantage of making the etching of the basal sections 310 even more selective vis-à-vis the other sections 400, 500 of the pad. Indeed, the oxidised silicon is etched more easily than crystalline silicon. This embodiment is, for example, possible with an etching, for example, by hydrofluoric (HF) acid, to selectively and isotropically etch the SiO₂ formed during the step of oxidising to the basal sections 300.

This embodiment combining reduction of the section and amorphisation of the basal sections makes it possible to considerably favour the deformation of the latter during coalescence, which makes it possible to reduce the density of dislocations even more.

Modification by Porosification of the Basal Sections

FIG. 5 illustrates an embodiment, wherein the modification of the basal section 300 is obtained by porosification of the crystalline material constituting this section 300.

The modified basal section 310 thus has a material different from that of the basal section 300. In particular, the elastic moduli (Young's modulus E₃₁₀ and shearing modulus □) of the modified basal section 310 is such that E₃₁₀≤E₃₀₀ the ratio between the two values being a function of the porosification ratio of the material in question, E₃₀₀ being the Young's modulus of the basal section 300 before modification. For example, for silicon, the following publication can be referred to: Phys. Status Solidi C 6, No. 7, 1680-1684 (2009)/DOI 0.1002/pssc.200881053.

Thus, the stresses generated during the coalescence of crystallites 510A1-510A1 carried by two adjacent pads 1000A1-1000A2 make it possible to deform the modified basal sections 310. The latter, thus make it possible to make up for the disorientations of the adjacent crystallites and to obtain platelets 550A, 550B without or with very few dislocations at the coalescence seals 560.

Preferably, this modification by porosification is done in the whole section d₃₀₀ of the basal section 300.

Preferably, this porosification does not alter the sections 400, 500 surmounting the basal section 300. This porosification is therefore selective.

Preferably, this porosification isotropically affects the material of the base substrate 10. Thus, a portion 101b of the support substrate 100 supporting the basal sections 300 is also made porous. The portion of the support substrate 100 which is not made porous is referenced 101a in FIG. 5.

Preferably, for this embodiment, it is avoided that the epitaxial growth occurs between the pillars and from the substrate 100. To obtain a truly selective epitaxial growth, it is possible to passivate free faces, after the porosification and before the epitaxial growth. This passivation of free faces is, for example, obtained by oxidation.

This embodiment by porosification is in particular advantageous, when the material constituting the basal sections 300 is particularly hard. Such is the case of silicon carbide SiC.

In more detail, this porosification can be done with the following parameters: the porosification of the silicon is usually done in an HF-based electrolyte (preferably HF and isopropyl (IPA) alcohol, for example). According to the type of p- or n-doping, the conditions are different: in the case of p-doped Si, controlling the method is done by the potential applied, while for n-doping, an irradiation with visible light (high power, for example greater than 700 Watts) is necessary. Contrary to other materials (like GaN), the porosification is not totally selective with respect to doping. However, the kinetics of the reactions vary according to the doping (resistivity of the plate). The challenge of this step is to define the conditions to only porosify the base of the Si pillar without porosifying the GaN. The AlN barrier and the difference of porosification mechanisms between p or n Si and GaN makes it possible to determine this method window.

This embodiment is thus particularly advantageous, when the doping of the silicon plate is controlled. This doping of the silicon plate can be done by implantation or during epitaxy. It also makes it possible, when it is associated with an oxidation, to carry out this oxidation at a very low temperature.

Modification by Porosification and by Transformation of the Basal Sections

FIG. 6 illustrates an embodiment wherein the modification of the basal section 300 is obtained by:
porosification of the section of the basal section 300, and
transformation, preferably by amorphisation, preferably by oxidation, of the crystalline material constituting the basal section 300.

Thus, this embodiment combines the embodiments described above, in reference to FIGS. 2 and 5. All the features, steps and technical effects mentioned above in reference to FIGS. 2 and 5, are applicable to the embodiments illustrated in FIG. 6.

According to an example, the porosification of the section of the basal section 300 by etching is done before amorphisation. Thus, in the case of Si, the material is conductive, when it is made porous. According to another example, the porosification of the section of the basal section 300 by etching is done after amorphisation.

This embodiment combining porosification and amorphisation of the basal sections makes it possible to considerably favour the deformation of the latter during coalescence, which makes it possible to reduce the density of dislocations even more.

Other Variants of Modification of the Basal Sections

According to an embodiment, the modification of the basal section 300 is obtained by:
reduction of the section of the basal section 300, then before or after the section reduction,
porosification of the crystalline material constituting the basal section 300.

The porosification can be done before or after the reduction of the section. When the porosification is done before the reduction of the section by etching, the selectivity of the etching is improved.

According to another embodiment, the modification of the basal section 300 is achieved by carrying out each of the following steps:
reduction of the section of the basal section 300, and
porosification of the crystalline material constituting the basal section 300, and
transformation, preferably by amorphisation of the crystalline material constituting the basal section 300.

All the combinations of order of these steps can be considered. However, as indicated above, it is often preferable that the porosification is done before amorphisation if the latter leads to making the material non-conductive.

The embodiments combining several types of modifications make it possible to further improve the capacity of the modified basal section 310 to be modified during the coalescence state, thus favouring the reduction of the density of the dislocations.

In all the embodiments mentioned above, it is preferable that the epitaxial growth does not occur between the pads. For this, it can be provided that the growth is selective, such that it does not occur from the upper face 110 of the substrate 100. For this, this upper face 110 can be modified. This modification can be obtained by oxidation or by nitridation of this upper face 110.

In a combined or alternative manner, it can be provided that the pads are sufficiently high, such that the coalescence of the crystallites is achieved before the growth from the upper face 110 of the substrate 100 reaches the crystallites. This embodiment is, for example, particularly adapted with the AlN growth, since for this material, the lateral growth speed is low.

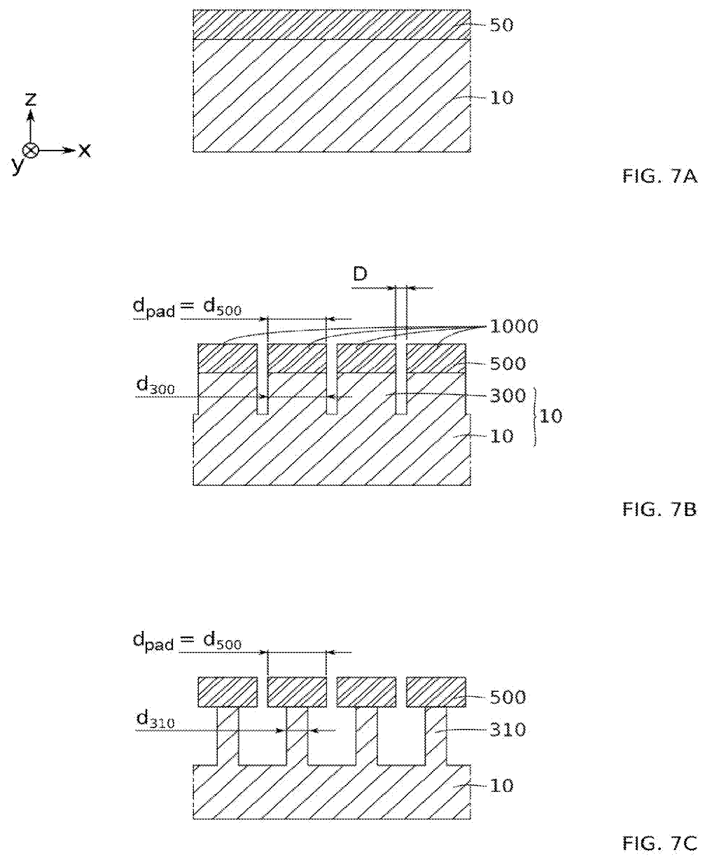

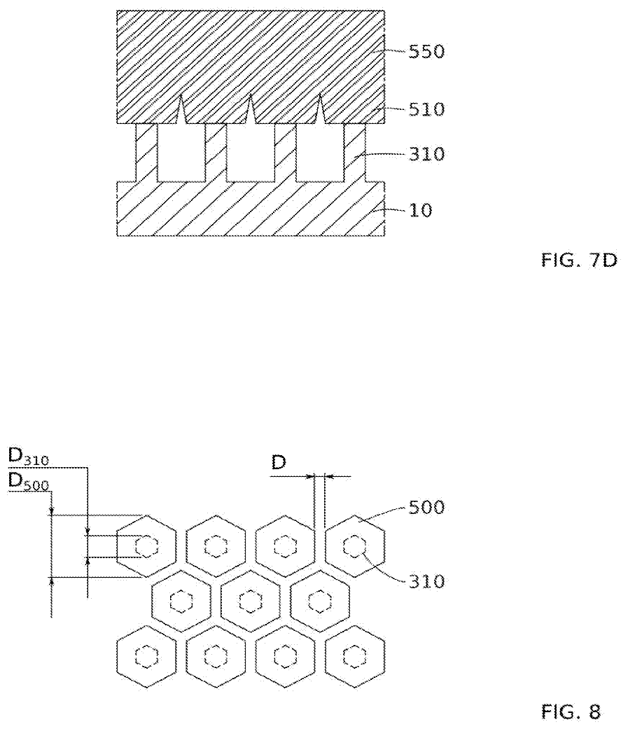

The method proposed has proved to be particularly advantageous for obtaining III-N material layers or platelets, the growth of which is made complex, due to the coalescence between adjacent crystallites being done with difficulty or late. This advantage will now be explained in reference to FIGS. 7A to 8.

For some III-N materials, the growth is done mainly in a direction parallel to the main direction in which the pads extends. This is the direction c, (axis z on the to orthogonal system of FIG. 7A). Conversely, the crystallites grow at a low speed in the plane xy. This delays the coalescence of the crystallites carried by the adjacent pads. This difficulty is encountered when this relates to obtaining an AlN layer, for example.

The method proposed, makes it possible to both:
define germination sections 500 distant from one another by a low distance D,
define modified basal sections 310 to be made easily deformable.

With the distance D being low, the adjacent crystallites come very rapidly into contact with one another to coalesce. This can be obtained by defining germination sections 500 having large sections d₅₀₀. Nevertheless, these large sections d₅₀₀ are not disadvantageous, since the basal sections 300 are modified to be made easily deformable, in order to avoid the formation of dislocations.

FIG. 7A represents the base substrate 10 surmounted by a germination layer In this example, the base substrate 10 can be made of silicon and the germination layer can be made of AlN. The thickness of the latter is, for example, around 300 nanometres.

FIG. 7B illustrates the result of an etching step, which makes it possible to define the pads 1000 in the germination layer 50 and the base substrate 10. The pads 1000 of this stack thus each comprising a basal section 300 and a germination section 500. The pads 1000 are spaced apart by a distance D and having a section referenced dead or d₅₀₀.

FIG. 7C illustrates the result of a step of modifying basal sections 300. In this non-limiting example, this modification step comprises a reduction by etching of the section of the basal sections 300, until obtaining a reduced section d₃₁₀ a lot smaller than the section d₅₀₀. FIG. 8 illustrates, as a top view, this step illustrated in FIG. 7C (it will be noted that if the crystallites have hexagonal sections, FIGS. 7A to 7C correspond to broken cross-sectional views passing through the diagonals of the hexagons).

FIG. 7D illustrates the result of the epitaxial growth step. The crystallites 510 coalesce to form a platelet 550. Even though the growth in the plane xy is slow, the reduced distance D makes it possible that this coalescence occurs rapidly.

In view of the description above, it clearly appears that the present invention proposes a particularly effective solution for obtaining one single nitride layer 550 or a plurality of epitaxial layers 550, having a very low density of dislocations, while relaxing the dimensional stresses on the initial definition of the pads in the base structure 20. to Moreover, the method proposed makes it possible to use bulk substrates and does not require the use of more expensive substrates, such as SOI substrates.

The method proposed thus makes it possible to considerably reduce the costs of obtaining a nitride layer.

Moreover, this method makes it possible to obtain nitride layers having both a high thickness and a very low density of dislocations. This method thus has considerable advantages for producing power components requiring high III-N material thicknesses.

The invention is not limited to the embodiments described above and extends to all the embodiments covered by the claims.

1. A method for obtaining at least one nitride layer based on a first III-N material, the method comprising the following successive steps:
providing a stack comprising a support substrate and a plurality of pads extending from the support substrate, the pads being distributed over the support substrate so as to form at least one pad assembly, each pad comprising at least:
one crystalline and silicon-based basal section extending from an upper face of the support substrate,
one crystalline germination section, and made from a second III-N material and based on at least one from among gallium (Ga), indium (In) and aluminium (Al), carried by the basal section and having a top,
selectively modifying the basal section with respect to the germination section so as to form a modified basal section having a lower rigidity than the basal section before modification, and
after modification of the basal section, epitaxially growing a crystallite from the top of at least some of the pads of the assembly and continuing the epitaxial growth of the crystallites until coalescence of the crystallites carried by adjacent ones of at least some of the pads of the assembly, so as to form the nitride layer on the pad assembly,
wherein the step of modifying the basal section being configured to, during the coalescence of the crystallites, deform the basal section, so as to make up for a disorientation of crystallites carried by two adjacent pads.

2. The method according to claim 1, wherein providing the stack comprising a plurality of pads comprises:
providing a base structure comprising at least:
a crystalline, preferably silicon-based base substrate, and
at least one germination layer surmounting the base substrate,
defining in the base structure, by etching through a whole thickness of the germination layer and through a portion only of a thickness of the base substrate, the plurality of pads, said etching defining:
in the germination layer, the germination section of each pad, and
in the base substrate, the basal section of each pad and the support substrate from which the basal section of each pad extends.

3. The method according to claim 2, wherein the etching to define the plurality of pads in the base structure comprises using an etching mask surmounting the germination layer, the etching mask being made by ultraviolet photolithography.

4. The method according to claim 1, wherein selectively modifying the basal section comprises an etching of the basal section selectively to the germination section 7 so as to form a modified basal section having a section d₃₁₀ smaller than a section d₅₀₀ of the germination section.

5. The method according to claim 4, wherein d₃₁₀≤0.8*d₅₀₀.

6. The method according to claim 1, wherein selectively modifying the basal section comprises transforming the basal section so as to make the material of the basal section more easily deformable.

7. The method according to claim 6, wherein transforming the material of the basal section comprises an at least partial amorphisation of the basal section, selectively to the germination section, so as to form a modified amorphous basal section the amorphisation being obtained by oxidation or by nitridation of the basal section.

8. The method according to claim 7, wherein the amorphisation is obtained by oxidation of the basal section, the basal section being made of silicon and the modified basal section being made of SixOy, x and y being non-zero integers.

9. The method according to claim 7, wherein the amorphisation is obtained by oxidation of the basal section and wherein the modified basal section has a behaviour of a viscous material and has a vitreous transition temperature T_{vitreous transition}, the epitaxial growth being carried out at a temperature T_{epitaxy}, such that:
T_{epitaxy}≥k1×T_{vitreous transition}, with k1≥>0.8.

10. The method according to claim 1, wherein selectively modifying the basal section comprises:
transformation of the basal section, and
before or after the transformation, etching of the basal section selectively to the germination section.

11. The method according to claim 1, wherein selectively modifying the basal section comprises a porosification of the basal.

12. The method according to claim 11, wherein selectively modifying the basal section comprises:
transformation of the basal section, and
before the transformation, the porosification of the basal section.

13. The method according to claim 1, wherein selectively modifying the basal section comprises at least two of following steps:
etching of the basal section selectively to the germination section,
said porosification of the basal section, and
transformation of the basal section.

14. The method according to claim 1, wherein selectively modifying the basal section comprises at least the following three steps carried out in the following order:
etching of the basal section selectively to the germination section,
said porosification of the basal section, and
said transformation of the basal section.

15. The method according to claim 1, wherein the pads are distributed over the support substrate so as to form a plurality of pad assemblies and the epitaxial growth step is interrupted before the crystallites belonging to two distinct assemblies coalesce, such that the layer formed on each assembly forms a platelet, the platelets being distant from one another.

16. The method according to claim 1, wherein the germination sections are separated by a distance D and a section d₅₀₀ of the germination sections is such that D<d₅₀₀.

17. The method according to claim 1, wherein the selectively modified is performed such that a force F1 that must be applied to obtain a given deformation of the modified basal section is less than 0.8*F2, F2 being a force that must be applied to obtain an identical deformation of a non-modified basal section.

18. The method according to claim 1, wherein the basal section is made of one from among Si, SiGe or SiC.

19. The method according to claim 1, wherein the second III-N material is identical to the first III-N material.
